(19) United States
(12) Patent Application Publication
(10) Pub. No.: US 2023/0179441 A1
(43) Pub. Date: Jun. 8, 2023

(54) PLATFORM FOR THE INTEGRATION OF OPERATIONAL BIM, OPERATIONAL INTELLIGENCE, AND USER JOURNEYS FOR THE SIMPLIFIED AND UNIFIED MANAGEMENT OF SMART CITIES

(71) Applicant: EUTECH CYBERNETIC PTE LTD, Singapore (SG)

(72) Inventors: Bandu JAYANATH WEWALAARACHCHI, Singapore (SG); Haritharan GUNASINGHAM, Singapore (SG); Haran SHIVINAN, Sri Lanka (LK); Lakshita SANJEEWA WIJERATHNE, Sri Lanka (LK)

(21) Appl. No.: 17/939,302

(22) Filed: Sep. 7, 2022

Related U.S. Application Data
(63) Continuation of application No. 16/603,461, filed on Oct. 7, 2019, now abandoned.

(30) Foreign Application Priority Data
Apr. 7, 2017 (SG) 10201702888X

(51) Int. Cl. H04L 12/28

(52) U.S. Cl. CPC H04L 12/2823; H04L 12/2812; H04L 12/2816

(57) ABSTRACT

A “metadata model of a city’s Internet of Everything and use thereof to implement citizen engagement through ‘user journeys’ and system intelligence through automated response logic. A framework that allows system integrators to build a metadata model of a city’s IoE by extracting building structure and device information from conventional CAD BIM files to automatically populate the metadata model to provide building modeling functionality and 3D-walkthrough capability for building and infrastructure operations(“Operational BIM”), which metadata model then enables city managers to implement user journeys and system intelligence, in incremental fashion, as the business needs of the city evolves.

### BACKGROUND OF THE INVENTION

### Field of the Invention

This invention relates to the field of smart infrastructure management - also known as Smart City solutions.

### Description of the Background

The field of infrastructure management has historically been limited to “silo-based” applications and operations, in which data captured through devices and human data entry stays in the applications in which it was captured or entered. Where integration across systems is required, custom solutions are made by solution integrators. These custom solutions are typically designed to serve trained operators, such as facilities managers or building engineers.

### SUMMARY OF THE INVENTION

### The IoT and the IoE

Since the advent of the internet, city system infrastructures have grown in sophistication and variety. During last decade, many internet-based devices have made their way to marketplace - ushering in the era of the Internet of Things (IoT), and building, building complex, neighborhood, town and city infrastructures are evolving from ‘systems and devices’ to the “Internet of Everything” (IoE) -which includes every device, system, network, application, cloud service, and even person, that is connected to the internet. Indeed, any person with a smartphone is now a node of the IoE. In order to be effective and efficient, system integration must no longer be merely between ‘systems’-- it must include IoE.

### Smart City - Smart Management of Infrastructure

The widely growing adoption of digital technologies to manage cities, with the goal of enhancing performance of city operations, reducing cost and improving service to citizens (end-users of systems), demands a sophisticated approach to infrastructure management. These infrastructures include both physical systems such as energy and water supply, transportation, etc., and software systems such as supervisory and data acquisition (SCADA), maintenance management, lease management, etc.

The complexity of smart city implementation comes from two fundamental challenges: first, a smart city according to the invention is a ‘living system’ which must constantly evolve to serve city needs and to reflect constantly changing and moving citizenry/population; and secondly, people and skills involved in modeling city services are different from people and skills involved in system implementation and integration. That is, the smart city solution of the invention must be highly intuitive, as mobile users have a very short operation/attention timespan -- they expect a system to provide ONLY what they need to carry out their operation.

The present smart city solution addresses this by modeling ‘user journeys’- providing a template containing the anticipated exact steps (interactions with the system of the invention) that a particular type of user will require or carry out achieve an objective.

### Building Information Models: 3D to 6D

Building Information Modelling (“BIM”) software and files can present the entire structure and infrastructure of a building in a single file or file set representing the 3D environment of the building. BIM software and files allow a user to zoom in and ‘walk through’ a 3D visualization of a building, forward, backward, up and down (navigate in 3D space). Moreover, current BIM software and files and extend this visualization into a ‘time dimension’ by providing different ‘versions’ of drawing elements associated with ‘time’. This allows someone to stop in 10^{th} floor (while navigating through 3D space) and take a walk through ‘time’ to see how, for example, the 10^{th} floor was constructed step by step - or go towards future to see how it will look after construction is finished. BIM software and files with the time capability is referred to as 4D BIM.

BIM software and files that can also accommodate ‘materials and costing’ information to BIM drawing elements, allowing users to plan and optimize resource usage and logistics for undisrupted building construction process, are often referred to as 5D BIM.

6D BIM software and files include information such as Assets installed in the building, and recommended operating procedures, such as emergency evacuations, that allow building lifecycle management and sustainability.

### Solution - A Metadata Model of the City’s IoE

The present invention implements a “metadata model of a city’s IoE,” and using the metadata model of the city’s IoE to implement citizen engagement through ‘user journeys’ and system intelligence through automated response logic. Furthermore, present invention extracts building structure and device information from conventional CAD BIM files to automatically populate and update the metadata model thereby providing building modeling functionality and and 3D-walkthrough capability for operations of building infrastructure. The improved metadata model, including building structure and device information extracted from conventional CAD BIM files, and the corresponding additional functionality, may sometimes herein be referred to as “Operational BIM-Activated Metadata Model” or simply ‘Operational BIM’. More specifically, the present invention provides a framework that allows system integrators to build a metadata model of a city’s IoE, which metadata model then enables city managers to implement user journeys and system intelligence, in incremental fashion, as the business needs of the city evolves.

The following is a summary of some of the features of the present invention:
a) The invention extracts metadata from the Internet of Everything, i.e., 3D, 4D, 5D and/or 6D Building Information Modeling software and files, networks of computers, subsystems, applications, devices, people (their smartphones), and cloud services, including data and methods. Each of these items, and any person with a smartphone, is a node of the IoE.
b) The invention sets up relationships between individual metadata elements to form a metadata model for the city;
c) The invention processes events, and applies analytics to filter and qualify events - this feature is sometimes referred herein as operational intelligence;
d) The invention sets up automated sequences of actions to ‘self manage’ known situations;
e) The invention sets up ‘user journeys’;
f) The invention connects with end-users (citizens) through unified communication.
g) The invention maintains relationships between ‘things’ with the ability to dynamically update those relationships as new ‘things’ are introduced to the solution domain and when relationships between ‘things’ changes with time.
h) The invention can publish metadata model to third party systems and applications to receive and exchange metadata
i) The invention allows the presentation of metadata through 3D visualization to augment operational scenarios

### Example

A metadata model of a smart city having been built using the present invention, including all the devices, systems, subsystems, devices, networks, applications, data, etc., that are connected to the internet, the system receives metadata from a building control system reflecting a room temperature of 26 degrees, within normal parameters. However, the system of the present invention is monitoring metadata related to user-devices (mobile phones) of building occupants [metadata model] who are sending out Tweets indicating ‘office is hot.’ The system correlates the control system metadata concerning room temperature with metadata from other systems, i.e., mobile phones on the IoE [event processing & analytics], and the system qualifies the situation as “important to respond” and sends an SMS [unified communication] to the facilities manager of the building indicating that building occupants feel uncomfortably warm. The facilities manager opens his mobile app, and it will show a single page with the details of the problem, and also what system thinks the root cause is --- for example, perhaps an “energy saving” mode has automatically kicked in due to a sudden rise of dynamic energy price. The same mobile app page can give the facilities manager the option to turn off the energy saving mode, and will show how much extra it will cost the company, without the facilities manager having to navigate to various systems to gather such knowledge. This is an example of modeling a user (in this case, a facilities manager) journey.

Accordingly, there is provided according to the invention the following features:
a) Devices (generating information, and acting based on received information), applications (holding information and processing information), people (receiving information and acting based on them), and extracted metadata from BIM files are used to build, and part of, a single metadata model.
b) Building the model automatically, and modifying the metadata model continuously and dynamically as city elements change, using a variety of resources including BIM files, devices that monitor or reflect the movement of people in and out of buildings and in and out of the smart city, metadata and/or other information reflecting equipment status changes during operations, etc.
c) Use of metadata relationships to extract metadata from existing nodes or from subsystems (using connectors) to build & update metadata nodes.
d) Presentation of a metadata model in the form of 3D view using the visual elements extracted from BIM files;
e) Metadata model being ‘machine readable’ due to predefined templates defining well-known metadata structures.
f) Cross reference between existing metadata nodes (enabling progressive implementation).
g) Enabling/augmenting operational intelligence using the metadata model.
h) Citizen engagement through ‘user journeys’ (a sequence of operations that are specifically designed to achieve an objective) rather than merely enabling access to a bunch of applications
i) Applying such solution to ‘city wide infrastructure.’

Accordingly, there is provided according to the invention a system for building a meta-data model representing the infrastructure of a community, including buildings, building systems, building devices, building wide and tenant specific enterprise applications, (etc.), and using that meta-data model for the integrated management of the infrastructure of a community, where the infrastructure includes a plurality of network-connected infrastructure systems, subsystems, devices, and applications, and where the systems, subsystems, devices and applications are independent and unintegrated, the system including:
a user-defined machine-readable metadata model comprising predefined metadata node templates defining metadata structures for said infrastructure systems, subsystems, devices, and applications;
connector modules configured to collect metadata from said infrastructure systems, subsystems, devices, BIM files and applications;
an event engine that receives metadata from said connector modules and which populates metadata node templates using said metadata to create , populated metadata nodes;
a dynamic metadata map/model assembled by said event engine, comprising populated metadata nodes, including relationships between nodes based on said collected metadata;
3D visualizer allowing navigation through metadata model with respect to physical view of the building or city infrastructure and viewing metadata; and
pre-defined operation sequences, based on the occurrence of events received from the connector modules, which pre-defined operation sequences define a set of operations according to predicted end-user requirements in response to pre-selected events.

There is further provided according to an embodiment of the invention a system wherein the community is a city.

There is further provided according to an embodiment of the invention a system wherein the community is a single building.

There is further provided according to an embodiment of the invention a system in which one or more buildings are represented by BIM files generated during building construction which indicate various equipment and systems in the building and their relationships to one-another which may be used as a source of metadata

There is further provided according to an embodiment of the invention a system wherein the community is a collection of buildings.

There is further provided according to an embodiment of the invention a system wherein the community is a workplace or single-tenant space within a multi-tenant building where some subsystems (such as air conditioning) belong or are operated by the building and/or building management, while other subsystems (such as card access & CCTV) are owned and/or managed by the tenant.

There is further provided according to an embodiment of the invention a system according to which cross references are established between existing metadata nodes.

There is further provided according to an embodiment of the invention a system wherein the event engine is configured to build the dynamic metadata map automatically, continuously, and dynamically, modifying the metadata map as collected metadata changes.

There is further provided according to an embodiment of the invention connector software module that periodically scans evolving BIM files and compares updated versions to earlier versions of the same BIM file in order to extract any modified metadata and send said metadata to the event engine for processing.

There is further provided according to an embodiment of the invention a system wherein the event engine is configured to use metadata relationships to extract metadata from existing nodes or from subsystems to build and update metadata nodes.

There is further provided according to an embodiment of the invention the ability of the metadata model to publish information for third party systems and applications by means of API (application programming interface) to receive and exchange metadata.

There is further provided according to an embodiment of the invention a system wherein the dynamic metadata map/model contains metadata notes for a plurality of infrastructure systems, subsystems, devices, and/or applications that are involved in a service workflow, wherein a service workflow comprises a set of pre-selected information that presented to an end user and said predefined operation sequences.

There is further provided according to an embodiment of the invention a system wherein the predefined operation sequences comprise an end-to-end service workflow for end-users of the system by having metadata model undertake integration with multiple subsystems involved in the service workflow.

There is further provided according to an embodiment of the invention a system further including an analytics engine configured to identify and correlate events and to update existing events or create new events based on identified correlations.

There is further provided according to an embodiment of the invention a system wherein the event engine is configured to send commands to one or more of said infrastructure systems, subsystems, devices, and applications based on the receipt of one or more event conditions received by the event engine.

There is further provided according to an embodiment of the invention a system wherein the network comprises the Internet.

There is further provided according to an embodiment of the invention a system wherein the network comprises only private networks.

### BRIEF DESCRIPTION OF THE DRAWINGS

FIG. 1 shows how a user (e.g., a system integrator) has defined event processing logic in the metadata node template.

FIG. 2 shows a metadata model editor which a user can access to build a metadata template according to an embodiment of the invention.

FIG. 3 is another view of a metadata model editor which a user can access to build a metadata template according to an embodiment of the invention.

FIG. 4 is a diagram showing a metadata model according to an embodiment of the invention.

FIG. 5 is a representation of the extraction of metadata from subsystems to populate a metadata model according to an embodiment of the invention.

FIG. 6 is a representation of how metadata node relationships can be established using common metadata present in different metadata nodes.

FIG. 7 is a representation of how an embodiment of the invention reacts to new devices entering or interacting with the “Smart City.”

FIG. 8 is a representation of different parts of the invention and their relationships.

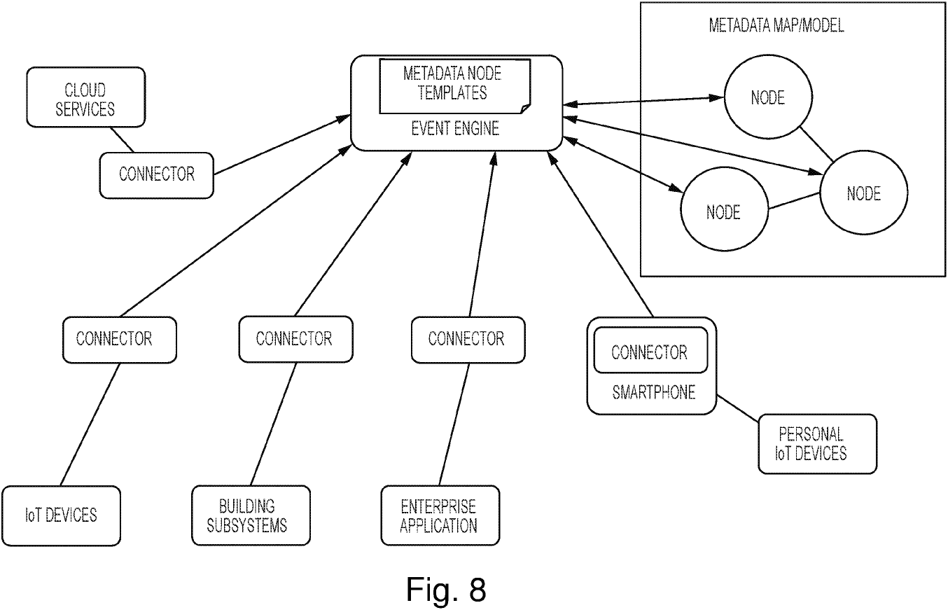

FIG. 9 is a representation of how (conventional) BIM file stores properties of equipment.

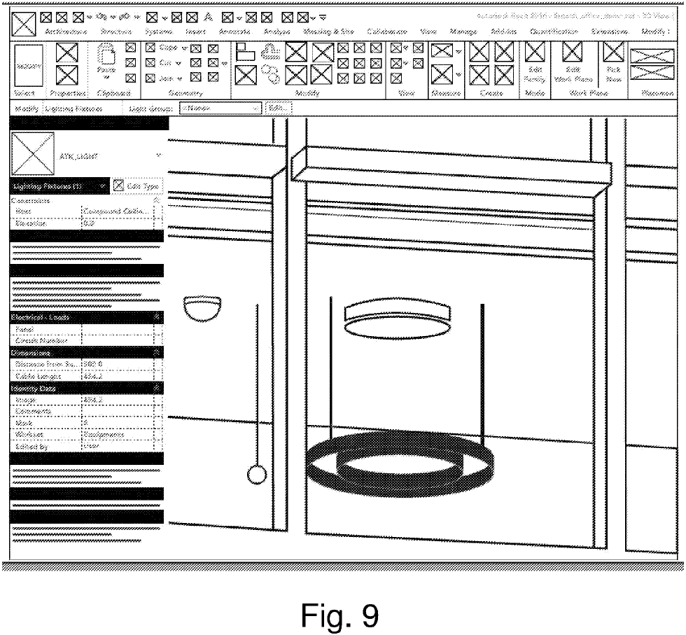

FIG. 10 is a conceptual representation of the invention performing the role of Operational BIM that holds properties of IoE - Internet of Everything.

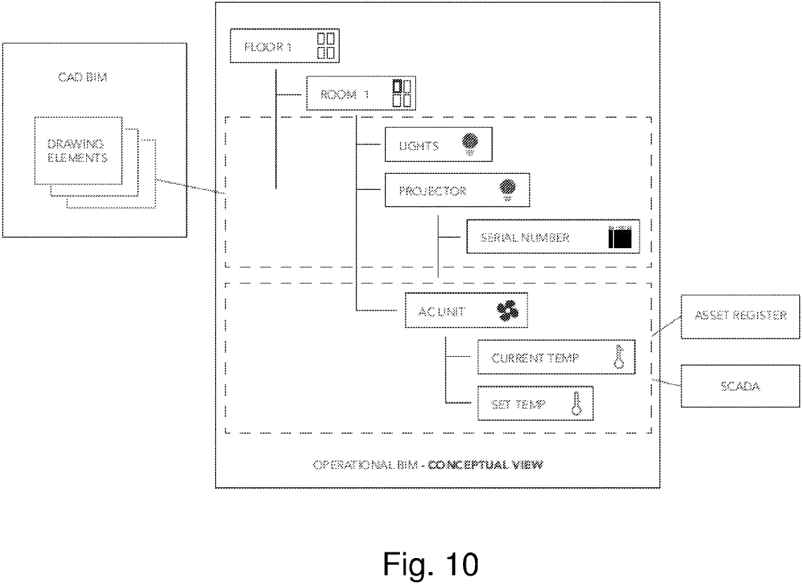

FIG. 11 is a representation of the architecture of connector that processes BIM files -‘scanner’.

FIG. 12 shows the process of extracting data from BIM files specific to Autodesk Revit software.

FIG. 13 shows the process of extracting data from BIM files specific to Autodesk Forge cloud service.

FIG. 14 shows how 3D visualization of the invention assists building operators to identify a false fire alarm.

FIG. 15 shows how 3D visualization of the invention assists building operators to identify a positive fire alarm and helps evacuation process.

FIG. 16 shows how 3D visualization of the invention assists building operators to safely carry out elevator test.

### DETAILED DESCRIPTION OF THE INVENTION

### Dynamic Metadata Map

The present invention may be used in any community (workplace, building, building complex, neighborhood, town, or city) that might benefit from the integrated management of infrastructure systems, the use or operation of which impacts or is impacted by devices, systems, networks, applications, and persons (smartphones) in the IoE. “Workplace” as used herein refers to a single-tenant space within a multi-tenant building where some subsystems (such as air conditioning) belong or are operated by the building and/or building management, while other subsystems (such as card access & CCTV) are owned and/or managed by the tenant. However, the invention is most useful in the case of a city wide IoE or other large collection of devices, systems, and networks, the members of which (in particular the people using smartphones) are constantly in flux, moving within the system, and moving into and out of the system. Using the case of a Smart City as an example, the system of the invention includes a metadata map or “model” that is made up of metadata nodes that represent the IoE -- each internet-aware device/entity in the city. Since this comprehensive metadata model includes people with smartphones who are constantly moving around and going in and out of the city, also referred to herein as the solution boundary, the metadata model is adapted to be constantly, dynamically, and automatically changing as the available metadata changes. According to a preferred embodiment, there will be only one metadata map for the entire city with millions of metadata nodes connected to each other directly or indirectly.

### Metadata Nodes

The metadata model is made up of metadata nodes. Each node is a collection of metadata. For example, ‘Meeting Room One’ is a Facility-type metadata node, and it carries metadata such as ‘Location’, ‘Seating Capacity’, ‘Amenities’, etc. Other types of metadata nodes include: Visitor, Staff, Equipment, Work Order, and Room Booking. In the case of Work Order and Room Booking types of metadata nodes, these metadata nodes represent transactions that are dynamically introduced while system is in operation. Further, a Room Booking metadata node may contain metadata of Facility (meeting room), Staff (host) and Visitor (attendee). Visitor-type metadata nodes might be identified by a telephone number or an email address; in this way, a visitor’s mobile phone constitutes a physical representation of the visitor, which in turn is represented in the invention as a metadata node on the system with, for example, the mobile phone’s telephone number or email address(es). Likewise, a Staff-type metadata node might also be identified by a telephone number, email address, name, organization, department and/or work location. An Equipment-type metadata node might include Asset-ID, Asset Category, Installed Location, Serving Locations (where it serves, which may be different from installed location), Assignee (User), Related Equipment, Make, Model and/or Serial number. A Work Order type metadata node might include Work Order ID, Service Category, Location, Work Description, Assigned Vendor/Technician, Supervisor and/or Deadline to Complete.

### Operational BIM

According to a preferred embodiment of the invention, a significant source of metadata for building of the metadata model is Building Information Modelling files, with the more advanced BIM (i.e., 5D and 6D) being more preferred; however 3D and 4D BIM files may be used.

### Events and Event Engine

Constructing and modifying of metadata nodes is done by an ‘event engine’. It receives metadata in the form of ‘events’. Events are generated by one or more Connector modules, described below.

Another exemplary event might be ‘Visitor V001 arrived at Gate G001’. Upon receiving new or modified metadata, the event engine either creates new metadata nodes or modifies existing nodes to absorb newly received information into metadata model. In another example, a staff member in the office may be represented by a Staff metadata node carrying two metadata (among others): Staff ID and Current Location.

Event filtering and processing is also done by the event engine, based on the logic defined in metadata model template. The metadata model is configured to allow a user to establish an ‘action sequence’ that defines how engine will process incoming events.

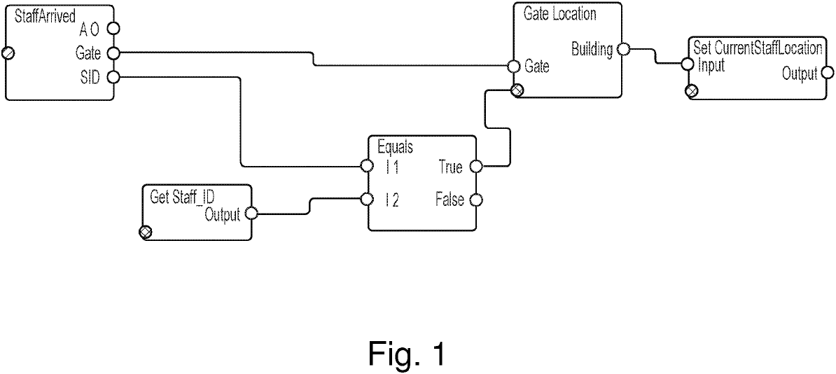

FIG. 1 shows how a user (e.g., a system integrator) has defined event processing logic in the metadata node template, which will be followed by the event engine. When Staff Arrived event is received, it has two metadata: Staff ID (SID) and Gate (through which Staff member arrived, and where event was captured). Event is compared against Staff ID to determine if the event belongs to this Staff member. If not, Event is ignored. Gate parameter that is associated with the Event is used to find the Location it belongs to, then assign that Location as Current Location metadata of Staff member. This forms a new connection between Staff node and Location node. As Staff moves around the building, more such events will arise, and Staff’s Current Location will be dynamically updated.

### Metadata Node Template

A central feature of the invention is a metadata node template, which is defined by the user (e.g., system integrator) and which defines how a metadata node should represent an entity, how metadata nodes should be connected to one-another. A metadata node template is a passive element that describes the contents of a node, which contents constitute instructions to the event-engine for assembly of the nodes and the relationships between them (the metadata nodes and relationships together constituting the metadata model/map). All instructions to the event engine go into the template which is editable by system integrator to modify behavior of the entire system.

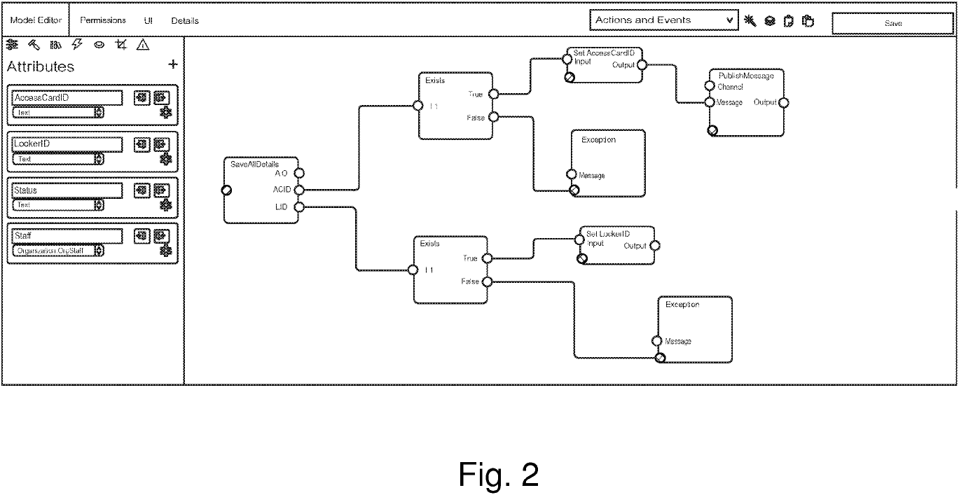

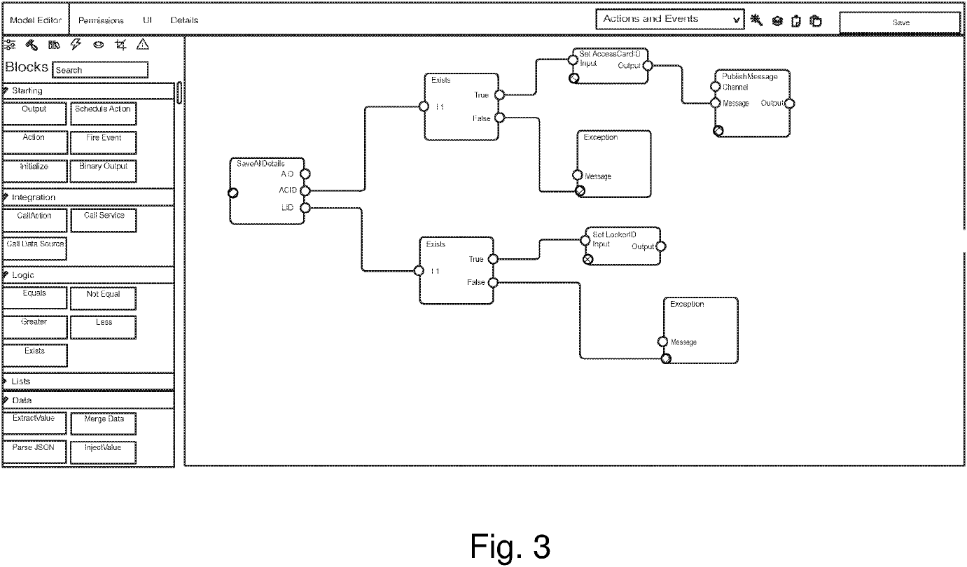

The user builds the metadata template using a metadata model editor, see FIGS. 2 and 3. The metadata model editor walks a user through the selection of various types of metadata nodes, the metadata they include, and actions to take as events are collected and processed by the event engine. For example, the ‘Visitor in Building’ node template would identify ‘Arrived Gate’, ‘Meeting Location’ and ‘Host’ as metadata placeholders. Upon receiving ‘visitor arrived’ event, new ‘Visitor in Building’ node would be created by event engine to represent Visitor V001.

### Forming Metadata Model

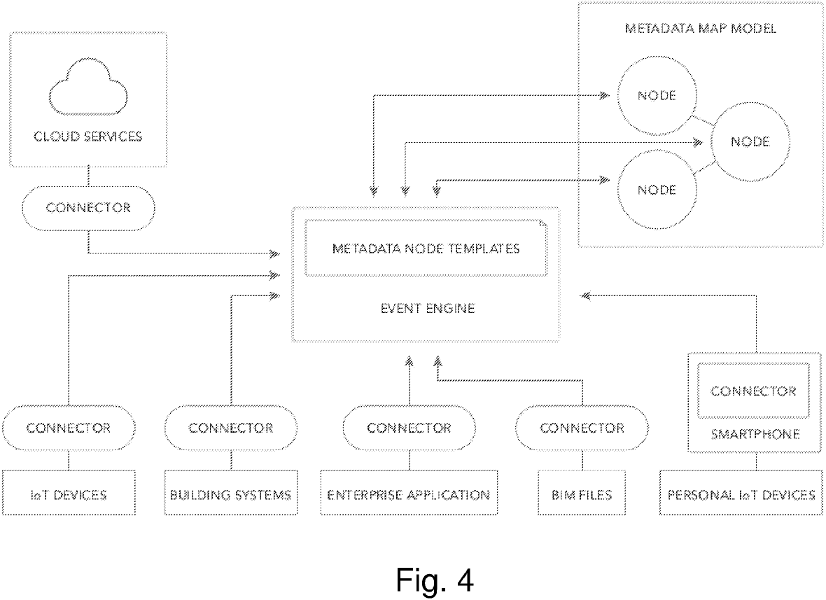

Referring to FIG. 4, the ‘metadata model’ is formed by connecting metadata nodes through common metadata that exists in different nodes. This is done by the event engines as part of the processing of received events. In the above example, upon receiving ‘Visitor V001 arrived at gate G001’ event, two embedded metadata (visitor’s ID and gate’s ID) are extracted and stored in metadata placeholders in the node. Further, the metadata node template (Visitor in Building) also requests the event engine to identify ‘meeting location’ and ‘host’, to complete its structure. The event engine explores existing metadata models to find matching nodes and to extract missing metadata to complete the node as specified by node template. Once a metadata node is made (by the event engine), only ‘metadata elements’ in it can be modified in order to store information (such as Staff->Name) or to make a connection to another metadata node (such as Staff->CurrentLocation). Action sequences defined in the template are embedded in the node (like DNA), but not individually alterable, except using the metadata model editor. That is, action sequence portions of the metadata node do not change based on receipt or processing of metadata.

Thus, the Metadata map or model is the mesh or network of metadata nodes (built using metadata organized according to metadata note templates), which nodes are “connected” using the relationships that are reflected in the metadata. For example, Staff-JohnSmith node forms a metadata map (on a microscale) with Building-1251ndustrialDrive node when CurrentLocation metadata (of Staff-JohnSmith) carries the reference to Building-125IndustrialDrive. According to a preferred embodiment of the invention, the metadata map encompasses an entire city, with millions of metadata nodes constructed using collected metadata and assembled using metadata node templates, and the relationships between which are also defined by common metadata elements between metadata nodes.

### Extraction of Metadata From Subsystems

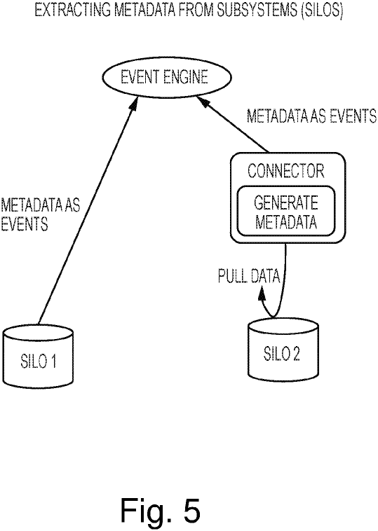

Referring to FIG. 5, the collection and/or extraction of metadata from systems, subsystems, networks, devices, applications and other elements of the IoE requires identifying data elements and methods of the silo-system. A “Connector” or “a software executable, identifies metadata from the various internet-aware elements of the IoE and sends them to the ‘event engine’ as ‘events’. According to an embodiment of the invention, there is a specific “Connector” for each subsystem/application that the invention collects information from so with Connector can effectively communicate with the target/corresponding/associated subsystem/application. The Connectors then transform the events into the format that event-engine can understand and send it to the event engine.

Alternatively, certain subsystems may be programmed to ‘push’ their metadata to the event engine directly, for example using their own Connectors configured to communicate with the system of the invention.

Examples of subsystems according to the invention include: air conditioning and heating systems, elevator systems, card access systems, CCTV systems and BMS (building management systems). Applications are addressed in the same way as any other subsystem. Mobile devices (such as a temperature sensor inside transportable refrigerator) report their status to a central server, and a Connector specific to that device’s system will pick it up from the central server. With respect to IoT-devices, they carry an IP-address that allows a Connector to directly address them. Smartphones and Networks are not considered a subsystem, although, a smartphone could represent a device or system through a connector (app) installed in the smartphone - for example, a connector placed in the smartphone could detect the proximity of iBeacon thereby determine current location of the Visitor and notify event engine.

### Correlation of Events

In the above example, the Connector may receive information reflecting that Visitor V001 is leaving the building, i.e., Visitor V001’s entry/exit card was presented at a security device-monitored exit point. At that point, Connector will raise ‘Visitor V001 left’ event. The event engine will correlate this event to existing ‘Visitor In Building’ node for V001 and make the necessary updates to reflect the current status.

### Navigation Through Metadata Model

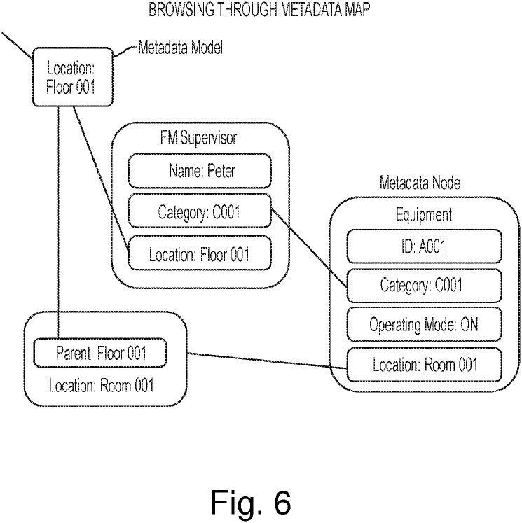

Referring to FIG. 6, the metadata model (collection of nodes) behaves similar to an ‘object collection’ in object oriented programming. That is, it forms a hierarchy (such as parent---child relationship in Locations), and it carries object attributes (such as node’s attributes representing metadata) and methods (actions represented by metadata).

For example, Location metadata (‘Room 001’) of equipment (‘A001’) gets attached to Location (‘Room 001’) attribute (metadata). Location hierarchy makes it immediately inherit parent location (‘Floor 001’) of Room 001. In this way, for example, any service that is looking for ‘photocopy machines’ (equipment of category ‘photocopy’) at Location ‘Floor 001’ will now find A001. The metadata model is a machine readable structure that does not require a human to browse through it.

### Cross References Between Metadata Nodes

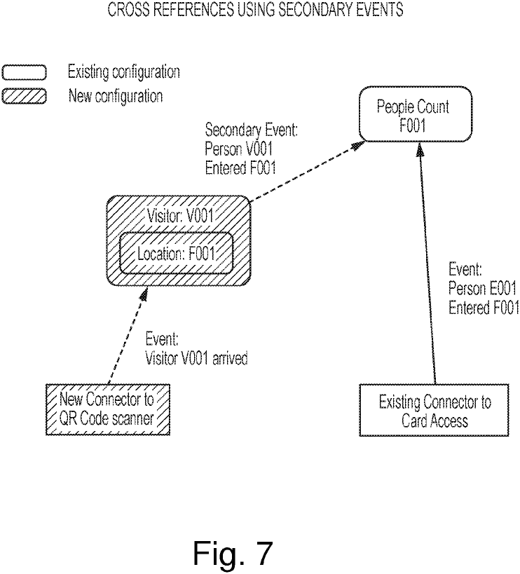

The invention allows system implementation to take place progressively. When the system (the metadata map) is expanded by adding new metadata node templates and connectors, the system of the invention generates/builds cross references between new nodes and existing nodes, without having to modify existing nodes. Referring, for example, to FIG. 7, originally implemented ‘people count’ map node (representing floor F001) maintains a list of employees in F001, collected from Card Access system, which is required in case of emergency evacuation. However, people count node is initially not aware of newly introduced event ‘Visitor001 arrived’, collected from QR Code scanner. Therefore, when a new visitor arrives, it doesn’t reflect on people count. The invention addresses this by having newly introduced Visitor node raise a ‘secondary’ event, ‘Person V001 entered F001’, which is recognized by original people count node (without having to modify it).

### Consolidated Actions - Orchestrations

As explained in the example above, ‘people count’ node has a list of people (both employees and visitors) who are currently in floor F001. The present invention allows a system integrator to define a single action for an event associated with a metadata node, e.g., “notify emergency evacuation” to everyone in F001 in the event that metadata is received reflecting an emergency situation, for example, a terrorist threat, fire or smoke, regardless of the silo that captured their presence on floor F001, whether it was Room Booking systems managing visitors, Work Order system managing contractors, or Space Management system managing seating locations for internal staff, and/or regardless of what silo captured the existence of an event, whether it was twitter feed from personal devices, email applications, a building/workplace fire detection/suppression system, and/or any other system or application.

### Automated Orchestrations

In some cases, it is required to automatically execute a series of actions, upon receiving an event. For example, People Count node may also be programmed to send SMS notification to all ‘persons’ in the particular floor when evacuation is ordered. More importantly, additional metadata that would identify a person as ‘handicapped’ could enable people count node to send a notification to facilities managers about locations of handicap persons in the building with instructions to provide special handling and assistance during the evacuation.

### Complex Event Processing (Analytics)

The invention includes an analytic engine that is able to process events and event---data to identify patterns and correlations. Examples are as follows:
Generate extended event based on repeated basic events within a given timespan (repeated “card rejected” event may generate “card reader faulty” event)
Correlate repeated events into a single event (repeated smoke---detected events indicates the single fire---incident event)
Transform data by consolidation of events, and include them as a new event; for example power consumption data collected/received in a series of events can be consolidated into “energy usage” data)
Predict secondary events by analyzing heuristics of primary events. For example, event history may indicate that a sustained ‘car park full’ event is generally followed by ‘dirty toilet’ feedback event for a particular restroom located next to car park. According to this example, the correlation between events is not configured by the user (system integrator or facilities manager); rather it is a correlation that is automatically identified by the analytic engine through analysis of event and event history data.

### Enabling Operational Intelligence

The present invention also processes events through analytics, allowing identifying meaningful events - both threats and opportunities, therefore enabling “operational intelligence.” For example, when one smoke detector reports a fire in a particular location, a new metadata node may be initiated to build necessary connections between the city’s metadata elements and to orchestrate certain actions such as notification to first responders. A few minutes later, more smoke detectors (in that Location) will likely report a fire. The system’s response to 2nd and 3rd smoke detected events should be different from the first event. They act as “confirmation” to first event, rather than initiating new fire---incident scenarios.

Similarly, additional metadata can be appended to an event to add “more sense.” In the same example above, if the first smoke detected alarm came from a detector that has produced a ‘false alarm’ a week ago, it would be wise to look for a 2nd confirmation from another detector, or a human confirmation, before the orchestration is carried out to respond to a fire.

### Enabling Predictive Operations

According to a preferred embodiment of the invention, operational intelligence produced through this invention is ‘machine readable’. As a result, it allows predetermined orchestrations to be executed based on complex event conditions. This allows operators to manage the infrastructure predictively. For example, in a large space such as the lobby of a shopping mall, it takes a long time for the air-conditioning system to react when more shoppers come into the mall. This is due to the natural delay in warmed air reaching air-conditioning ducts on the roof, where sensors are placed to recognize the rising temperature. The present invention allows system integrators to setup an orchestration that acts on ‘people count’ that is monitored through an independent system to influence air- conditioning system to produce more air-conditioning, predictively.

### Enabling Operational BIM

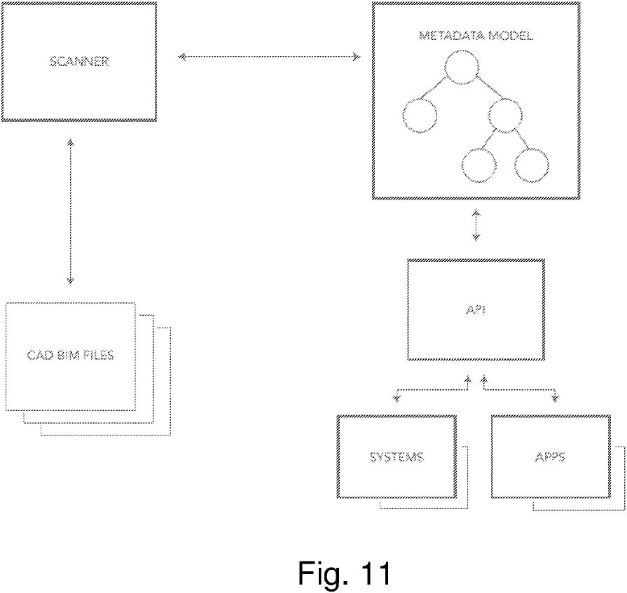

Scanner - Extracting Metadata from CAD BIM. See FIG. 11, Architecture of BIM File Connector.

The Scanner is a special Connector with specific knowledge of the CAD BIM file format. Different scanners are built for popular CAD BIM formats.

The Scanner is responsible for following primary tasks:
1. Identifying drawing elements that represent assets - such as air-condition equipment, lights, HVAC elements, security cameras, access control devices, smoke detectors, sprinkler systems, etc.;
2. Extracting element properties that carry metadata of assets - such as make/model/serial-number, etc.;
3. Extracting drawing properties/elements (i.e., external and internal walls, floors, ceilings, doors, windows, rooms, hallways, stairways, elevator wells, bathrooms, etc.) and pair them with metadata of the building assets to allow user to locate an asset in BIM drawing;
4. Reading Metadata Model to identify previously recognized elements hence filter out ‘changed metadata;’
5. Updating Metadata Model.

When the Scanner updates the Metadata Model, it sends metadata extracted from the CAD BIM file, it also associates two additional drawing metadata to identify the elements that represent a device or piece of equipment: BIM File ID and Element ID. These two pieces of information are used to ‘bind’ metadata nodes with the CAD BIM file’s drawing elements.

When scanning for ‘changes’ in the CAD BIM file relative to a scan of an earlier version of the same file, the Scanner uses this binding to match CAD BIM elements with metadata nodes of the invention.

The Scanner can be deployed either as a ‘manually executable’ process (to update on demand) or as an ‘automated background process’ to periodically synch Metadata Model with changes in CAD BIM.

Deployment architecture and exact procedure for identifying and extracting metadata from each type of CAD BIM file is different, but that is public knowledge, published by the manufacturer of the BIM design software under ‘SDK’ - software development kit.

### Example 1: Autodesk Revit Add-in

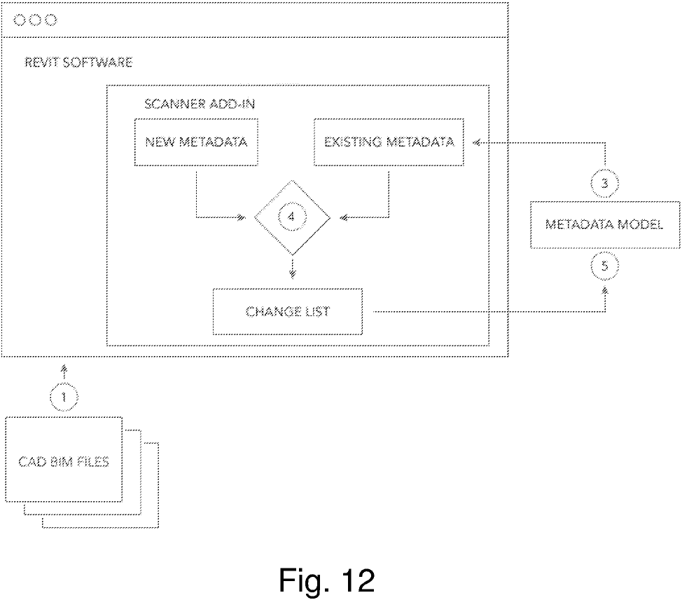

As shown in FIG. 12, the scanning process for the Scanner deployed as ‘add-in’ for Revit CAD software is as follows:
1. Load CAD BIM file into Revit software
2. Add-in identifies a filtered list of elements representing assets, and extracts their metadata
3. Read Metadata Model for previously uploaded metadata for same CAD BIM file
4. Compare and make a ‘change list’
5. Upload the changes to Metadata Model

### Example 2: Autodesk FORGE Cloud Service:

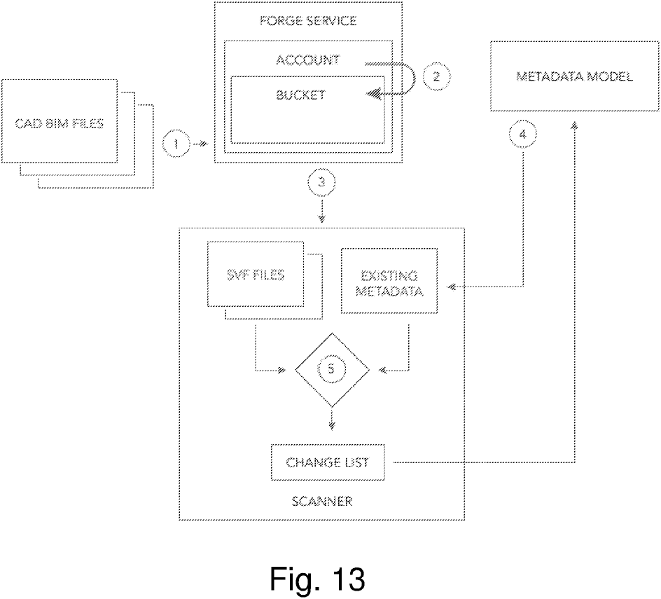

As shown in FIG. 13, the scanning process for the Scanner deployed to work with FORGE cloud service is as follows:
1. Load CAD BIM file into a bucket in FORGE cloud service account
2. Translate the CAD BIM file into common SVF format
3. Download SVF file into Scanner
4. Read Metadata model for previously uploaded metadata for same CAD BIM file
5. Compare and make a ‘change list’
6. Upload the changes to Metadata Model

### API for Metadata Exchange

The API (Application Programming Interface) comes in multiple forms:
REST API - that allows applications to communicate with Metadata Model using http/https
Event Service - that allows self-contained IoT devices to communicate through messaging protocols such as MQTT, which allows pushing data as well as receiving data through subscribed channels
SDK - a Software Development Kit that ‘wraps’ communication methodology as a library for software developers to incorporate into their applications/systems.

### Preferred Embodiments

### Automated Construction of The Asset Register

The Asset Register carries information about Assets and related information necessary for asset lifecycle management (maintenance/warranty/insurance information) and also for servicing of occupants with those assets (assignment/ownership/billing information).

Typically, this data is manually entered into the computer system. Although most of Asset Register software allows ‘data import’ electronically, such data should be collected and imported in one go. However, the building construction phase is very long and this information do not arrive at the same time to allow ‘full data import’. Also, some of the data changes often during operations.

The following example illustrates the significance of using Operational BIM-Activated Metadata Model for populating the Asset Register.

As part of construction phase, the physical details of an Asset (say, wall mounted TV) such as Installed Location, Make, Model and Serial Number will get populated in Operational BIM.

As a new Asset is added to the metadata model (say, imported from CAD BIM), the Asset Register will get notified about the new Asset through the connector (that connects Asset Register to Metadata Model), so it will extract information about the new Asset, automatically.

At a later point, when the accounting system updates the TV’s warranty certificate, the Connector for the accounting system will extract the metadata (such as Vendor, Expiry Date, etc.) and will generate an event and transmit it to the Metadata Model server, which allows the Metadata Model to update the Asset’s metadata. This action in turn will trigger a notification to Connectors that listen to changes in the Metadata model. The Connector that represents the Asset Register will grab that information and update it again, automatically.

Once the building goes into operation and Tenants are coming in, a leasing agreement is signed with a Tenant for leasing of the location where the TV is installed. This agreement transfers the Asset’s ownership to the Tenant for the duration of the leasing agreement. The Connector picks up the metadata about the new assignment (Tenant, effective date, etc.) and send it to the Metadata Model by raising an event.

This enables the Metadata Model to update its metadata (assignment) and also to make a new ‘metadata relationship’ between the Asset (TV) and the Metadata Node representing the Tenant.

When an operator searches for ‘assignments’, this relationship comes up thereby listing the TV as an asset assigned to this Tenant.

### Automated Configuration of SCADA System

The SCADA system of the building (often known as “BMS” - building management system) requires information about equipment (assets) in order to communicate with them. Two key pieces of information are: point-address (how to address a particular operational attribute) and protocol (how messages should be crafted such that device will understand).

Often, this data is manually entered into SCADA system when operations are setup. These are very ‘cryptic’ information and small mistake of a single character could result in a disaster. Therefore, it is highly desirable to automatically obtain this data from ‘system commissioning’ repository where this information is already captured in electronic form and verified during handing over phase.

As the building goes into the system commissioning phase, real-time communication with the equipment is established. When testing and commissioning a Light, for example, commissioning agent will verify that system is able to read the Light’s brightness and operating status (ON or OFF), and also will verify the system’s ability to change the brightness the light and turn it on/off.

The Metadata involved in this communication (how to address the equipment, what data to be sent to the device to perform control, etc.) gets stored in the Operational BIM-Activated Metadata Model. The process of metadata capture is the same as explained in previous section -‘automated construction of asset register’.

When a user wants to monitor the status of the Light, or to control the Light, the SCADA system will use the metadata extracted from Operational BIM to figure out how to communicate with the device, without having to ‘manually configure’ it.

Apart from allowing operators to monitor and control devices on demand, the SCADA system is also responsible of ‘keeping track’ of health of equipment and systems. For example, if room temperature rises beyond 27 degrees while the AC-Unit’s status is ON, it could indicate an equipment failure. This is known as ‘alarm’ and operators should be notified about it. Often, this notification is automated based on ‘maintenance contract’ information, and will be directly routed to the maintenance vendor.

However, if this alarm occurs while system maintenance is performed in that location, it could be part of their testing work. Therefore, it is desirable to ‘mask’ such false alarms to avoid unwanted confusions.

With access to Operational BIM, the SCADA system is able to find if the equipment that generated the alarm is under maintenance at that point, hence mask the alarm notification.

### Incident Management

Incident Management is one of the critical operations where ‘related information’ has an enormous value. The following scenario illustrates how Operational BIM-Activated Metadata Model can be used.

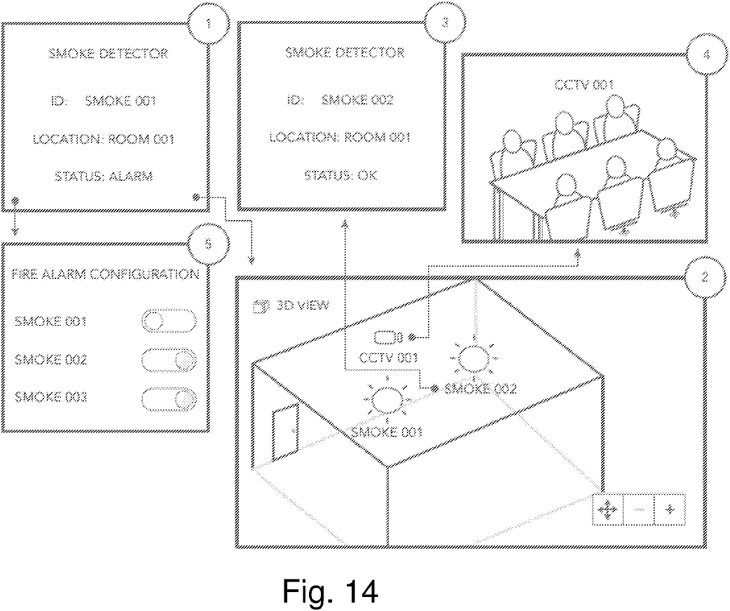

Referring to FIG. 14, (Mock-up screen showing negative-fire incident dashboard), a smoke detector has raised an alarm indicating that it detected a smoke, which could be an indication of fire.

The Fire system is programmed to enunciate the fire (activate strobes and sirens) in two minutes unless the building operator acknowledges the fire alarm by clicking a button on the fire panel (equipment mounted on the wall) or through the SCADA system. Normal practice is to acknowledge the alarm from control centre through the SCADA system.

Once the alarm is acknowledged, the fire system is programmed to extend the enunciation deadline by another 5 minutes to allow building operators to clear the smoke or disable the detector - if it is due to a false alarm.

This five-minute window is very critical, especially where false alarm could cause a heavy business damage (say, in a shopping mall), or when it has a potential to create a life-safety issue due to panic (say, in a hospital), or when it could create a security threat by opening unwanted door locks (say, in a prison or airport).

As described in section ‘Scanner - Extracting Metadata from CAD BIM’, asset metadata in Operational BIM also contains drawing metadata of CAD BIM.

With that, an operator is able to click on the smoke detector that generated the alarm and automatically zoom in to view the location where smoke is detected in. Then, the operator finds that there is a camera in that area. With Operational BIM’s ability to execute a process, the operator can zoom/pan the camera to the smoke detector’s location and visually verify that there is no smoke.

As the operator ‘walks through’ the 3D BIM, he may also notice there are two other smoke detectors in that room. With Operational BIM’s metadata relationships, the operator can quickly monitor the real-time status of the other two smoke detectors, and double-confirm that it is a sensor failure.

This allows the operator to disable a smoke detector to prevent enunciation of false alarm, and dispatch a technician to replace it.

### Dynamic Team Formation

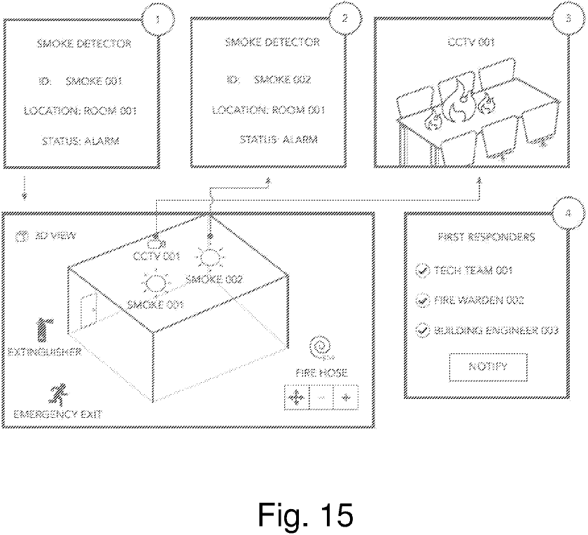

In an alternative situation of the above smoke detection scenario, if it happened to be an actual fire, the operator sitting in the control center needs to quickly find out who are the building operators near the fire area to execute a guided evacuation of building occupants. See FIG. 15 (Mock-up screen showing positive-fire incident dashboard ).

Operational BIM has been dynamically forming metadata relationships as indoor positioning data picks up presence of pre-registered personnel (building operators, fire wardens and others who are trained to assist public). As the incident management dashboard opens, it extracts metadata from Operational BIM, and it will assemble the most appropriate list of people to form the first responder team.

### Continuous Commissioning Test Procedures

When systems are commissioned, commissioning agents run various procedures to ensure systems work according to operational specifications. However, with time, these systems could deteriorate thereby reducing operational efficiency, lifespan and safety of people around them. This problem is solved by repeating these test procedures at predetermined time intervals — a procedure known as ‘continuous commissioning’. One well known example is fire drills where the entire system - including occupants’ ability to respond - is tested.

However, this requires complex logistics. First, it is necessary to dispatch operators and safety wardens to appropriate locations to handle any unexpected situation. Secondly, occupants need to be notified to ensure they do not overreact to the service breakdown. Thirdly, the SCADA system that is monitoring the building needs to be put on standby to avoid undesired notifications to go out to people and 3rd party systems.

As such, continuous commissioning requires so many people with specific knowledge of each vertical; therefore; the performance of certain required activities are sometimes neglected.

This problem is significantly reduced with the Operational BIM-Activated Metadata Model which maintains the central repository of all information in the building, and more importantly, their relationships.

For example, when an elevator’s backup battery has to be tested, the procedure requires cutting elevator power supply during its move, and check if it safely was brought down to nearest floor and the door is opened.

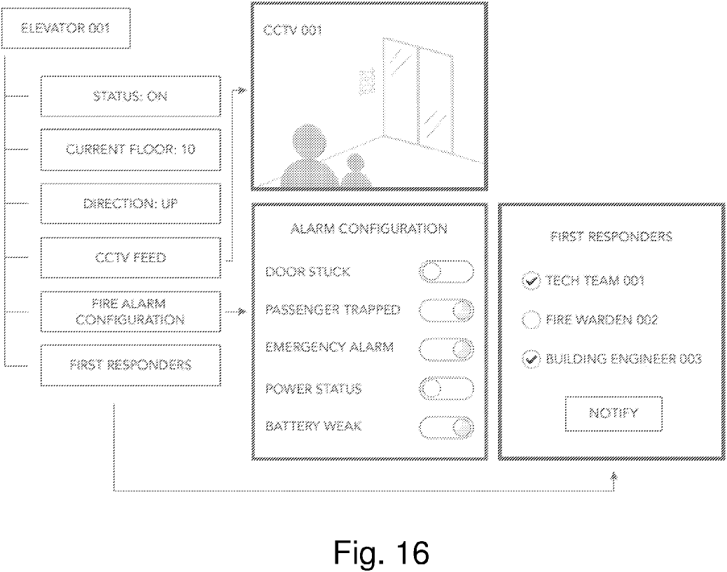

With Operational BIM, the operator has access to the elevator’s CCTV feed to ensure there are passengers inside, has the list of duty personal available in the building at that point in time to ensure they are alerted about the procedure to keep an eye, and access to SCADA systems alarm configuration to temporary disable them. See, e.g., FIG. 16 (Dashboard mock up showing elevator test).

1. A system for integrated management of the infrastructure of a community, where the infrastructure comprises a plurality of network-connected infrastructure systems, subsystems, devices, and building information modeling files and applications, and where the systems, subsystems, devices, and building information modeling files and applications are independent and unintegrated, the system comprising:
a user-defined machine-readable metadata model comprising predefined metadata node templates defining metadata structures for said infrastructure systems, subsystems, devices, and building information modeling files and applications;
connector modules configured to collect metadata from said infrastructure systems, subsystems, devices, and building information modeling files and applications;
an event engine that receives metadata from said connector modules and which populates metadata node templates using said metadata to create populated metadata nodes;
a dynamic metadata map/model assembled by said event engine, comprising populated metadata nodes, including relationships between nodes based on said collected metadata, and pre-defined operation sequences, based on the occurrence of events received from the connector modules, which pre-defined operation sequences define a set of operations according to predicted end-user requirements in response to pre-selected events.

2. A system according to claim 1, wherein said community is a city.

3. A system according to claim 1, wherein said community is a single building.

4. A system according to claim 1, wherein said community is a collection of buildings.

5. A system according to claim 1, wherein said community is a workplace or single-tenant space within a multi-tenant building where some subsystems (such as air conditioning) belong or are operated by the building and/or building management, while other subsystems (such as card access & CCTV) are owned and/or managed by the tenant.

6. A system according to claim 1, further comprising cross references between existing metadata nodes.

7. A system according to claim 1, wherein the event engine is configured to build the dynamic metadata map automatically, continuously, and dynamically, modifying the metadata map as collected metadata changes.

8. A system according to claim 1, wherein the event engine is configured to use metadata relationships to extract metadata from existing nodes or from subsystems to build and update metadata nodes.

9. A system according to claim 1, wherein said dynamic metadata map/model contains metadata notes for a plurality of infrastructure systems, subsystems, devices, and/or applications that are involved in a service workflow, wherein a service workflow comprises a set of pre-selected information that presented to an end user and said predefined operation sequences.

10. A system according to claim 1, wherein said predefined operation sequences comprise an end-to-end service workflow for end-users of the system by having metadata model undertake integration with multiple subsystems involved in the service workflow.

11. A system according to claim 1, further comprising an analytics engine configured to identify and correlate events and to update existing events or create new events based on identified correlations.

12. A system according to claim 1, wherein the event engine is configured to send commands to one or more of said infrastructure systems, subsystems, devices, and applications based on the receipt of one or more event conditions received by the event engine.

13. A system according to claim 1, wherein the network comprises the Internet.

14. A system according to claim 1, wherein the network comprises only private networks.

15. A system according to claim 1, wherein the connector modules are configured to periodically check for changes in building information modeling files and to update the metadata model when changes are discovered relative to earlier versions of said building information modeling files.

16. A system according to claim 1, further comprising a user interface display that provides a user with 3D visualization capability to navigate through the metadata model.

17. A system according to claim 1, further comprising an publishing API configured to allow third parties to receive and exchange metadata with the system.
